(19) United States
(12) Patent Application Publication
(10) Pub. No.: US 2026/0128730 A1
(43) Pub. Date: May 7, 2026

(54) TRANSVERSELY-EXCITED FILM BULK ACOUSTIC RESONATOR WITH MULTI-MARK INTERDIGITAL TRANSDUCER

(71) Applicant: Murata Manufacturing Co., Ltd., Nagaokakyo-shi (JP)

(72) Inventors: Greg DYER, Santa Barbara, CA (US); Bryant GARCIA, Mississauga (CA); Julius KOSKELA, Helsinki (FI)

(21) Appl. No.: 19/369,788

(22) Filed: Oct. 27, 2025

Related U.S. Application Data
(63) Continuation of application No. 17/950,019, filed on Sep. 21, 2022, now Pat. No. 12,489,421.
Application No. 17/950,019 is a continuation of application No. 17/388,745, filed on Jul. 29, 2021, now Pat. No. 12,088,281.
(60) Provisional application No. 63/144,977, filed on Feb. 3, 2021.

(51) Int. Cl. H03H 9/56; H03H 9/13; H03H 9/17

(52) U.S. Cl. CPC H03H 9/56; H03H 9/13; H03H 9/17

(57) ABSTRACT

An acoustic resonator is provided that includes a piezoelectric layer having at least a portion attached to a substrate either directly or via one or more intermediate layers; and a conductor pattern on the piezoelectric layer. The conductor pattern includes a multi-mark interdigital transducer having a plurality of interleaved fingers extending from opposing busbars, and a length between outermost fingers of the interleaved fingers. The IDT is divided along the length into at least three sections. A change in the mark between the at least three sections has a smaller effect on a resonance frequency of a primary shear acoustic mode of all of the at least three sections of the acoustic resonator in comparison to an effect that the change in the mark has on a spurious acoustic mode other than the primary shear acoustic mode of all of the at least three sections.

### CROSS REFERENCE TO RELATED APPLICATIONS

This application is a continuation of U.S. patent application Ser. No. 17/950,019, filed Sep. 21, 2022, which is a continuation of U.S. patent application Ser. No. 17/388,745, filed Jul. 29, 2021, now issued as U.S. Pat. No. 12,088,281, which claims priority to U.S. Provisional Ser. No. 63/144,977, filed Feb. 3, 2021, entitled CHIRPED XBAR ELECTRODES, the entire content of each of which are incorporated herein by reference.

This patent application is related to application Ser. No. 17/093,239, filed Nov. 9, 2020, entitled TRANSVERSELY-EXCITED FILM BULK ACOUSTIC RESONATOR WITH MULTI-PITCH INTERDIGITAL TRANSDUCER.

### TECHNICAL FIELD

This disclosure relates to radio frequency filters using acoustic wave resonators, and specifically to filters for use in communications equipment.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a pass-band or stop-band depend on the specific application. For example, a “pass-band” may be defined as a frequency range where the insertion loss of a filter is better than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

RF filters typically require many design trade-offs to achieve, for each specific application, the best compromise between performance parameters such as insertion loss, rejection, isolation, power handling, linearity, size and cost. Specific design and manufacturing methods and enhancements can benefit simultaneously one or several of these requirements.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels.

High performance RF filters for present communication systems commonly incorporate acoustic wave resonators including surface acoustic wave (SAW) resonators, bulk acoustic wave (BAW) resonators, film bulk acoustic wave resonators (FBAR), and other types of acoustic resonators. However, these existing technologies are not well-suited for use at the higher frequencies and bandwidths proposed for future communications networks.

The desire for wider communication channel bandwidths will inevitably lead to the use of higher frequency communications bands. Radio access technology for mobile telephone networks has been standardized by the 3GPP (3^{rd} Generation Partnership Project). Radio access technology for 5^{th} generation mobile networks is defined in the 5G NR (new radio) standard. The 5G NR standard defines several new communications bands. Two of these new communications bands are n77, which uses the frequency range from 3300 MHz to 4200 MHz, and n79, which uses the frequency range from 4400 MHz to 5000 MHz. Both band n77 and band n79 use time-division duplexing (TDD), such that a communications device operating in band n77 and/or band n79 use the same frequencies for both uplink and downlink transmissions. Bandpass filters for bands n77 and n79 must be capable of handling the transmit power of the communications device. WiFi bands at 5 GHz and 6 GHz also require high frequency and wide bandwidth. The 5G NR standard also defines millimeter wave communication bands with frequencies between 24.25 GHz and 40 GHz.

The Transversely-Excited Film Bulk Acoustic Resonator (XBAR) is an acoustic resonator structure for use in microwave filters. The XBAR is described in U.S. Pat. No. 10,491,291, titled TRANSVERSELY EXCITED FILM BULK ACOUSTIC RESONATOR. An XBAR resonator comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, band-pass filters, duplexers, and multiplexers. XBARs are well suited for use in filters for communications bands with frequencies above 3 GHz. Matrix XBAR filters are also suited for frequencies between 1 GHz and 3 GHz.

### BRIEF DESCRIPTION OF THE DRAWINGS

FIG. 1 includes a schematic plan view, two schematic cross-sectional views, and a detail view of a transversely-excited film bulk acoustic resonator (XBAR).

FIG. 2 is an alternative schematic cross-sectional view of an XBAR.

FIG. 3 is a graphic illustrating a shear horizontal acoustic mode in an XBAR.

FIG. 4 is a plan view of a multi-mark interdigital transducer (IDT).

FIG. 5 is a plan view of another multi-mark IDT.

FIG. 6 is a graph of mark as a function of position along the length of the IDT for a conventional IDT and another multi-mark IDT.

FIG. 7 is a graph of the magnitude of an input transfer function as a function of frequency for a filter with XBARs with a conventional IDT and a filter with XBARs multi-mark IDTs.

FIG. 8 is an expanded portion of the graph of FIG. 7.

FIG. 9 is a plan view of a multi-mark multi-pitch IDT.

FIG. 10 is a plan view of another multi-mark multi-pitch IDT.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

### Description of Apparatus

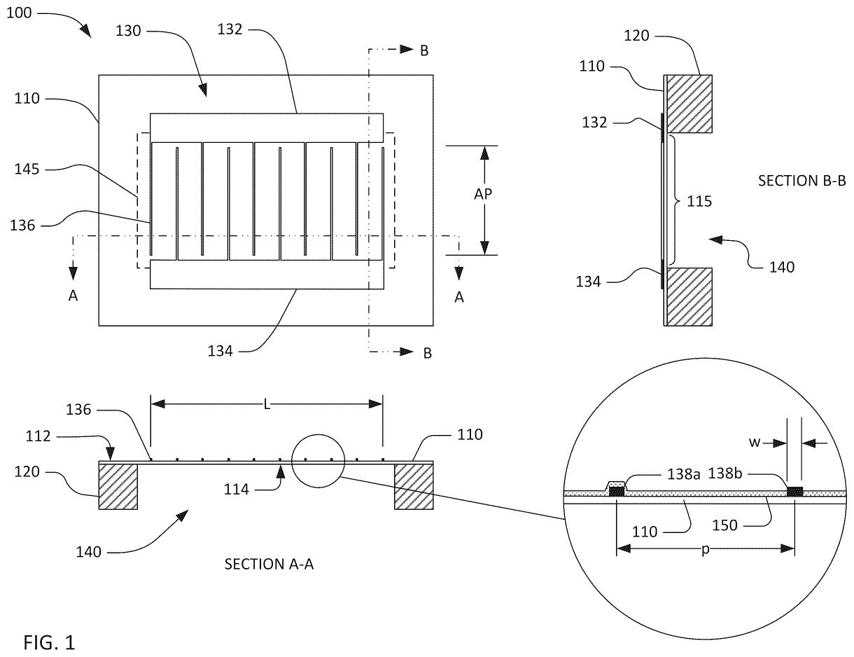

FIG. 1 shows a simplified schematic top view, orthogonal cross-sectional views, and a detailed cross-sectional view of a transversely-excited film bulk acoustic resonator (XBAR) 100. XBAR resonators such as the resonator 100 may be used in a variety of RF filters including band-reject filters, band-pass filters, duplexers, and multiplexers. XBARs are particularly suited for use in filters for communications bands with frequencies above 3 GHz.

The XBAR 100 is made up of a thin film conductor pattern formed on a surface of a piezoelectric plate 110 having parallel front and back surfaces 112, 114, respectively. The piezoelectric plate is a thin single-crystal layer of a piezoelectric material such as lithium niobate, lithium tantalate, lanthanum gallium silicate, gallium nitride, or aluminum nitride. The piezoelectric plate is cut such that the orientation of the X, Y, and Z crystalline axes with respect to the front and back surfaces is known and consistent. In the examples presented in this patent, the piezoelectric plates are Z-cut, which is to say the Z axis is normal to the front and back surfaces 112, 114. However, XBARs may be fabricated on piezoelectric plates with other crystallographic orientations.

The back surface 114 of the piezoelectric plate 110 is attached to a surface of the substrate 120 except for a portion of the piezoelectric plate 110 that forms a diaphragm 115 spanning a cavity 140 formed in the substrate. The portion of the piezoelectric plate that spans the cavity is referred to herein as the “diaphragm” 115 due to its physical resemblance to the diaphragm of a microphone. As shown in FIG. 1, the diaphragm 115 is contiguous with the rest of the piezoelectric plate 110 around all of a perimeter 145 of the cavity 140. In this context, “contiguous” means “continuously connected without any intervening item”. In other configurations, the diaphragm 115 may be contiguous with the piezoelectric plate around at least 50% of the perimeter 145 of the cavity 140.

The substrate 120 provides mechanical support to the piezoelectric plate 110. The substrate 120 may be, for example, silicon, sapphire, quartz, or some other material or combination of materials. The back surface 114 of the piezoelectric plate 110 may be bonded to the substrate 120 using a wafer bonding process. Alternatively, the piezoelectric plate 110 may be grown on the substrate 120 or attached to the substrate in some other manner. The piezoelectric plate 110 may be attached directly to the substrate or may be attached to the substrate 120 via one or more intermediate material layers (not shown in FIG. 1).

“Cavity” has its conventional meaning of “an empty space within a solid body.” The cavity 140 may be a hole completely through the substrate 120 (as shown in Section A-A and Section B-B) or a recess in the substrate 120 under the diaphragm 115. The cavity 140 may be formed, for example, by selective etching of the substrate 120 before or after the piezoelectric plate 110 and the substrate 120 are attached.

The conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved. The interleaved fingers overlap for a distance AP, commonly referred to as the “aperture” of the IDT. The center-to-center distance L between the outermost fingers of the IDT 130 is the “length” of the IDT.

The first and second busbars 132, 134 serve as the terminals of the XBAR 100. A radio frequency or microwave signal applied between the two busbars 132, 134 of the IDT 130 excites a primary acoustic mode within the piezoelectric plate 110. As will be discussed in further detail, the primary acoustic mode is a bulk shear mode where acoustic energy propagates along a direction substantially orthogonal to the surface of the piezoelectric plate 110, which is also normal, or transverse, to the direction of the electric field created by the IDT fingers. Thus, the XBAR is considered a transversely-excited film bulk wave resonator.

The IDT 130 is positioned on the piezoelectric plate 110 such that at least the fingers of the IDT 130 are disposed on the diaphragm 115 of the piezoelectric plate which spans, or is suspended over, the cavity 140. As shown in FIG. 1, the cavity 140 has a rectangular shape with an extent greater than the aperture AP and length L of the IDT 130. A cavity of an XBAR may have a different shape, such as a regular or irregular polygon. The cavity of an XBAR may have more or fewer than four sides, which may be straight or curved.

For ease of presentation in FIG. 1, the geometric pitch and width of the IDT fingers is greatly exaggerated with respect to the length (dimension L) and aperture (dimension AP) of the XBAR. A typical XBAR has more than ten parallel fingers in the IDT 110. An XBAR may have hundreds of parallel fingers in the IDT 110. Similarly, the thickness of the fingers in the cross-sectional views is greatly exaggerated.

Referring to the detailed cross-sectional view, a front-side dielectric layer 150 may optionally be formed on the front side of the piezoelectric plate 110. The “front side” of the XBAR is, by definition, the surface facing away from the substrate. The front-side dielectric layer 150 may be formed only between the IDT fingers (e.g. IDT finger 138b) or may be deposited as a blanket layer such that the dielectric layer is formed both between and over the IDT fingers (e.g. IDT finger 138a). The front-side dielectric layer 150 may be a non-piezoelectric dielectric material, such as silicon dioxide or silicon nitride. The thickness of the front side dielectric layer is typically less than or equal to the thickness of the piezoelectric plate. The front-side dielectric layer 150 may be formed of multiple layers of two or more materials.

The IDT fingers 138a and 138b may be aluminum, an aluminum alloy, copper, a copper alloy, beryllium, gold, tungsten, molybdenum or some other conductive material. The IDT fingers are considered to be “substantially aluminum” if they are formed from aluminum or an alloy comprising at least 50% aluminum. The IDT fingers are considered to be “substantially copper” if they are formed from copper or an alloy comprising at least 50% copper. Thin (relative to the total thickness of the conductors) layers of other metals, such as chromium or titanium, may be formed under and/or over and/or as layers within the fingers to improve adhesion between the fingers and the piezoelectric plate 110 and/or to passivate or encapsulate the fingers and/or to improve power handling. The busbars 132, 134 of the IDT may be made of the same or different materials as the fingers.

Dimension p is the center-to-center spacing or “pitch” of the IDT fingers, which may be referred to as the pitch of the IDT and/or the pitch of the XBAR. Dimension w is the width or “mark” of the IDT fingers.

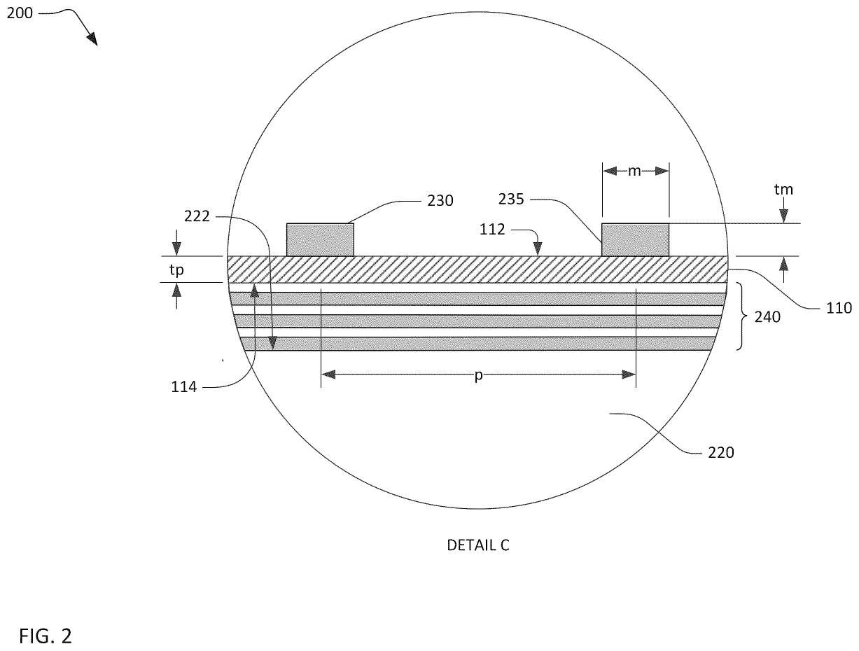

FIG. 2 shows a detailed schematic cross-sectional view of a solidly mounted XBAR (SM XBAR) 200. SM XBARs are first described in patent U.S. Pat. No. 10,601,392. The SM XBAR 200 includes a piezoelectric plate 110 and an IDT (of which only fingers 230 and 235 are visible). The piezoelectric layer 110 has parallel front and back surfaces 112, 114. Dimension tp is the thickness of the piezoelectric plate 110. The width (or mark) of the IDT fingers 230, 235 is dimension m, thickness of the IDT fingers is dimension tm, and the IDT pitch is dimension p.

In contrast to the XBAR device shown in FIG. 1, the IDT of an SM XBAR is not formed on a diaphragm spanning a cavity in a substrate (120 in FIG. 1). Instead, an acoustic Bragg reflector 240 is between a surface 222 of a substrate 220 and the back surface 114 of the piezoelectric plate 110. The acoustic Bragg reflector 240 is both disposed between and mechanically attached to a surface 222 of the substrate 220 and the back surface 114 of the piezoelectric plate 110. In some circumstances, thin layers of additional materials may be disposed between the acoustic Bragg reflector 240 and the surface 222 of the substrate 220 and/or between the Bragg reflector 240 and the back surface 114 of the piezoelectric plate 110. Such additional material layers may be present, for example, to facilitate bonding the piezoelectric plate 110, the acoustic Bragg reflector 240, and the substrate 220.

The acoustic Bragg reflector 240 includes multiple dielectric layers that alternate between materials having high acoustic impedance and materials have low acoustic impedance. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As will be discussed subsequently, the primary acoustic mode in the piezoelectric plate of an XBAR is a shear bulk wave. Each of the layers of the acoustic Bragg reflector 240 has a thickness equal to, or about, one-fourth of the wavelength of a shear bulk wave having the same polarization as the primary acoustic mode at or near a resonance frequency of the SM XBAR 200. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide, and diamond. All of the high acoustic impedance layers of the acoustic Bragg reflector 240 are not necessarily the same material, and all of the low acoustic impedance layers are not necessarily the same material. In the example of FIG. 2, the acoustic Bragg reflector 240 has a total of six layers. An acoustic Bragg reflector may have more than, or less than, six layers.

As shown in FIG. 2, the IDT fingers 230, 235 have rectangular cross-sections. The IDT fingers 230, 235 may have some other cross-section, such as trapezoidal, T-shaped, or stepped. The IDT fingers 230, 235 are shown as single layer structures which may be aluminum or some other metal. IDT fingers may include multiple layers of materials, which may be selected to have different acoustic loss and/or different acoustic impedance. When multiple material layers are used, the cross-sectional shapes of the layers may be different. Further, a thin adhesion layer of another material, such as titanium or chrome, may be formed between the IDT fingers 230, 235 and the piezoelectric plate 110. Although not shown in FIG. 2, some or all IDT fingers may be disposed in grooves or slots extending partially or completely through the piezoelectric plate 110.

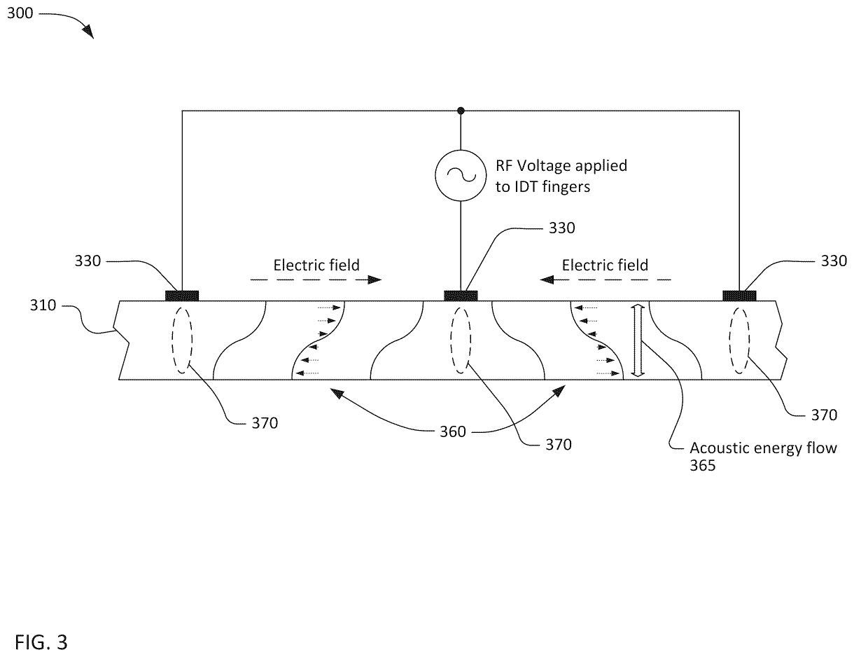

FIG. 3 is a graphical illustration of the primary acoustic mode of interest in an XBAR. FIG. 3 shows a small portion of an XBAR 300 including a piezoelectric plate 310 and three interleaved IDT fingers 330 which alternate in electrical polarity from finger to finger. An RF voltage is applied to the interleaved fingers 330. This voltage creates a time-varying electric field between the fingers. The direction of the electric field is predominantly lateral, or parallel to the surface of the piezoelectric plate 310, as indicated by the arrows labeled “electric field”. Due to the high dielectric constant of the piezoelectric plate, the RF electric energy is highly concentrated inside the plate relative to the air. The lateral electric field introduces shear deformation which couples strongly to a shear primary acoustic mode (at a resonance frequency defined by the acoustic cavity formed by the volume between the two surfaces of the piezoelectric plate) in the piezoelectric plate 310. In this context, “shear deformation” is defined as deformation in which parallel planes in a material remain predominantly parallel and maintain constant separation while translating (within their respective planes) relative to each other. A “shear acoustic mode” is defined as an acoustic vibration mode in a medium that results in shear deformation of the medium. The shear deformations in the XBAR 300 are represented by the curves 360, with the adjacent small arrows providing a schematic indication of the direction and relative magnitude of atomic motion at the resonance frequency. The degree of atomic motion, as well as the thickness of the piezoelectric plate 310, have been greatly exaggerated for ease of visualization. While the atomic motions are predominantly lateral (i.e. horizontal as shown in FIG. 3), the direction of acoustic energy flow of the excited primary acoustic mode is substantially orthogonal to the surface of the piezoelectric plate, as indicated by the arrow 365.

An acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. High piezoelectric coupling enables the design and implementation of microwave and millimeter-wave filters with appreciable bandwidth.

The XBAR primary acoustic mode is mostly bulk in nature, which can result in weak frequency dependence on mark and pitch. Thus, chirping (or variance) of mark, or mark and pitch, in the IDT of the XBAR can potentially suppress undesirable spurious modes that depend upon mark and/or pitch, such as metal and propagating modes, with only slight broadening of the primary mode resonance.

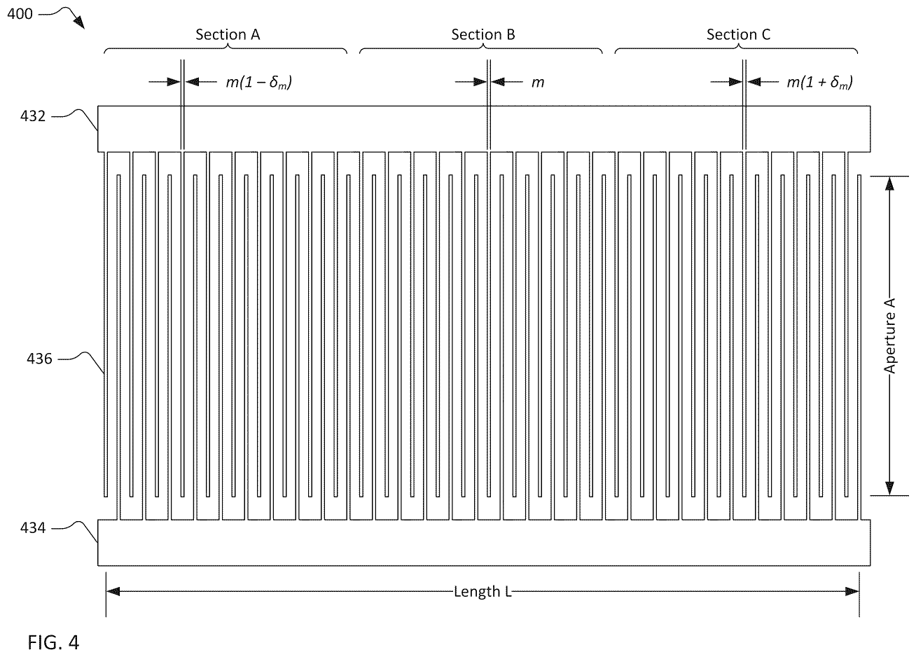

FIG. 4 is a plan view of an exemplary multi-mark IDT 400. A “multi-mark IDT” is an IDT where the mark of the IDT fingers varies along the length of the IDT. At any given point along the length, the mark may not vary across the aperture of the IDT. Further, the pitch, can be constant over the entire IDT. The multi-mark IDT 400 may be a portion of an XBAR such as the XBAR 100 of FIG. 1.

The multi-mark IDT 400 includes a first busbar 432, and a second busbar 434, and a plurality of interleaved fingers such as finger 436. The interleaved fingers extend alternately from the first and second busbars 432, 434. The multi-mark IDT 400 is divided into three sections, identified as Section A, Section B, and Section C, along the length L of the IDT. Each of Sections A, B, and C includes 20 fingers, for a total of 60 fingers in the multi-mark IDT 400. The use of three sections and 60 fingers is exemplary. An IDT may have more than or fewer than 60 total fingers. An IDT may be divided along its length into two or more sections, each of which includes a plurality of adjacent fingers. The total number of fingers may be divided essentially equally between the two or more sections. In this context, “essentially” means “as close as possible.” For example, an IDT with 100 fingers divided into three sections with 33, 34, and 33 fingers is considered to be divided essentially equally. The total number of fingers may be divided unequally between the two or more sections.

In this example, the fingers in Section B have mark m, which is the nominal mark of the IDT. The finger of Section A have a mark of m(1−δₘ), and the fingers of Section C have a mark of m(1+δₘ). δₘ is greater than 0 and less than or equal to 0.05. δₘ may typically be less than 0.01. δₘ may be selected during a filter design to achieve the most effective reduction of spurious modes. At any point along the length L of the IDT 400, the mark is constant across the aperture A. The pitch of the IDT fingers is constant and the same in all sections. When an IDT is divided into two sections or more than three sections, the maximum mark may be m(1+δₘ) and the minimum mark may be m(1−δₘ).

In the example multi-mark IDT 400, the mark increases monotonically from left (as seen in the figure) to right. This is not necessarily the case in all multi-mark IDTs. The sections of a multi-mark IDT may be arranged in some other order. Further, in the multi-mark IDT 400, the change in mark between adjacent sections is constant. This is also not necessarily the case in all multi-mark IDTs. The change in mark between adjacent sections may be the same or different.

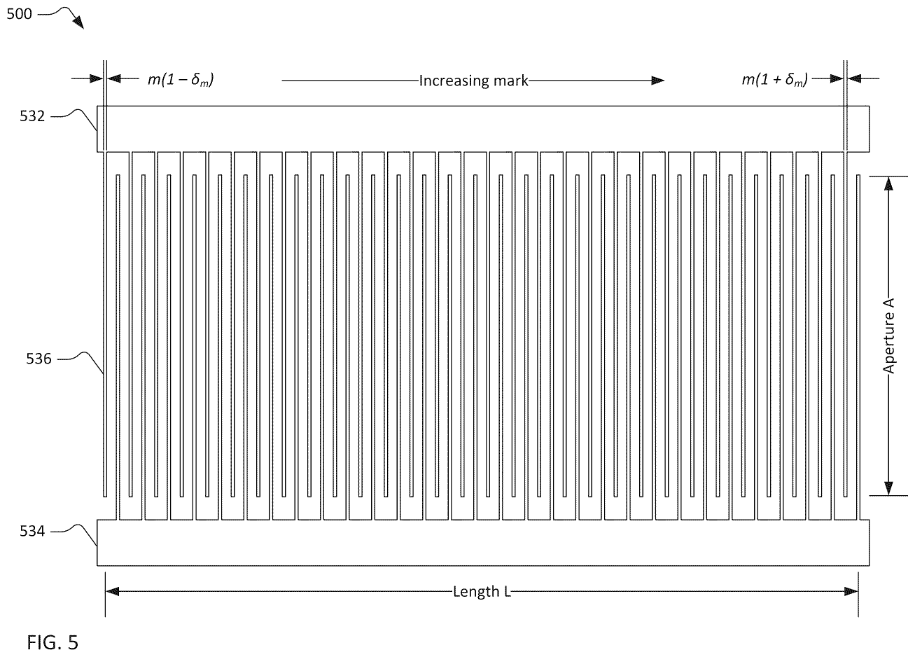

FIG. 5 is a plan view of another multi-mark IDT 500 with continuously varying mark. The IDT 500 includes a first busbar 532, and second busbar 534, and a plurality of interleaved fingers such as finger 536. The interleaved fingers extend alternately from the first and second busbars 532, 534. The IDT 500 is not divided into sections, but rather has a continuous change in mark for the fingers 536 along its length L. The IDT 500 has 60 fingers, which is exemplary. An IDT may have more than or fewer than 60 total fingers. The multi-mark IDT 500 may be a portion of an XBAR such as the XBAR 100 of FIG. 1.

As shown in FIG. 5, the mark at the left edge of the IDT 500 is m(1−δₘ), and the mark at the right edge of the IDT 500 is m(1+δₘ). The mark varies continuously between these two extremes. The variation in mark may typically, but not necessarily, be a linear function of position along the length L of the IDT. δₘ is greater than 0, less than or equal to 0.05, and typically less than 0.01. δₘ may be selected during a filter design to achieve the most effective reduction of spurious modes. At any point along the length of the IDT 500, the mark is constant across the aperture A. The pitch of the IDT fingers is constant over the entire IDT.

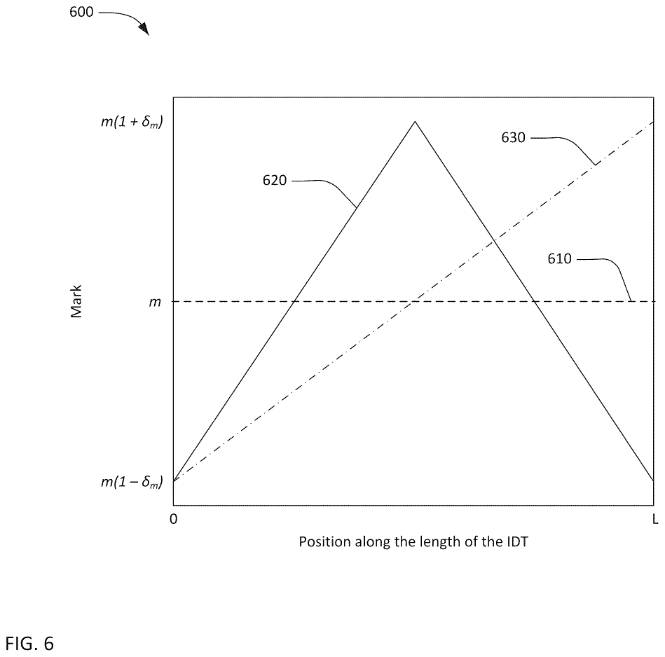

FIG. 6 is a graph 600 of mark as a function of position along the length of the IDT for a conventional IDT and another exemplary multi-mark IDT. Dashed line 610 shows mark as a function of position along the length of the IDT for a conventional IDT where mark is not chirped. Solid line 620 shows mark as a function of position along the length of the IDT for a multi-mark IDT with chirped mark. In this example, a linear gradient is applied to the mark of the multi-mark IDT, such that the chirp has a triangular profile. There is a difference of 0.5 nm in the mark of each sequential finger, such that a mark of a widest finger is 20 nm more than a width of the narrowest finger. Dot dashed line 630 shows mark as a function of position along the length of the IDT for another multi-mark IDT with chirped mark where a linear gradient is applied to the mark of the multi-mark IDT. Other exemplary IDTs can have other differences in the mark between sequential fingers, e.g., differences in a range from 0.1 nm to 0.9 nm, and a difference between the widest finger and the narrowest finger can be other values, e.g., in a range from 1 nm to 100 nm.

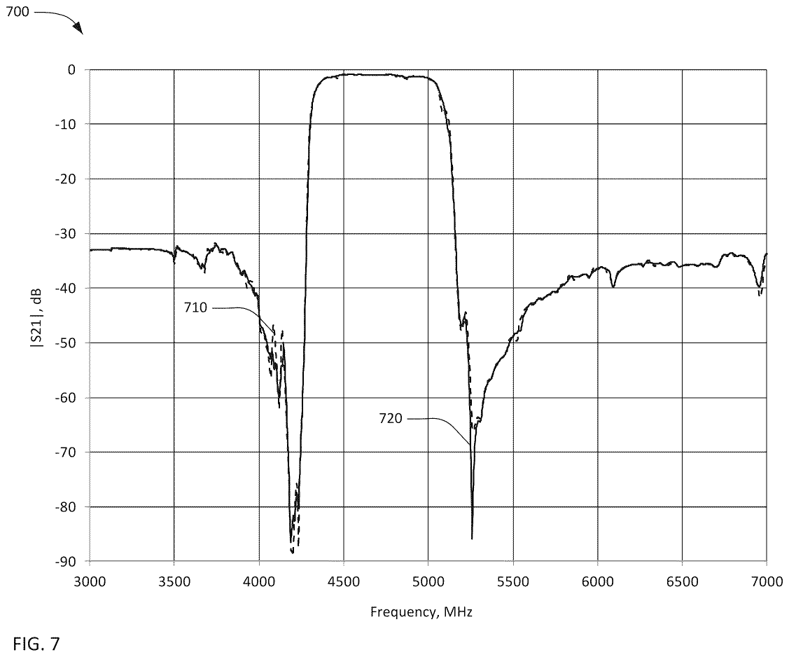

FIG. 7 is a graph 700 of the magnitude of S2,1, the input/output transfer function, for two bandpass filters implemented with XBAR devices. The S2,1 data was determined by simulation of the two filters using a finite element method. The dashed curve 710 is a plot of S2,1 for a first filter using XBARs with conventional IDTs. The solid curve 720 is a plot of S2,1 for a second bandpass filter that has multi-mark IDTs but is otherwise identical the first bandpass filter. Comparison of the curves 710 and 720 shows the passbands of the two filters are very similar. Compared to the first filter, the second filter with multi-mark IDTs exhibits reduced peak admittance of spurious modes.

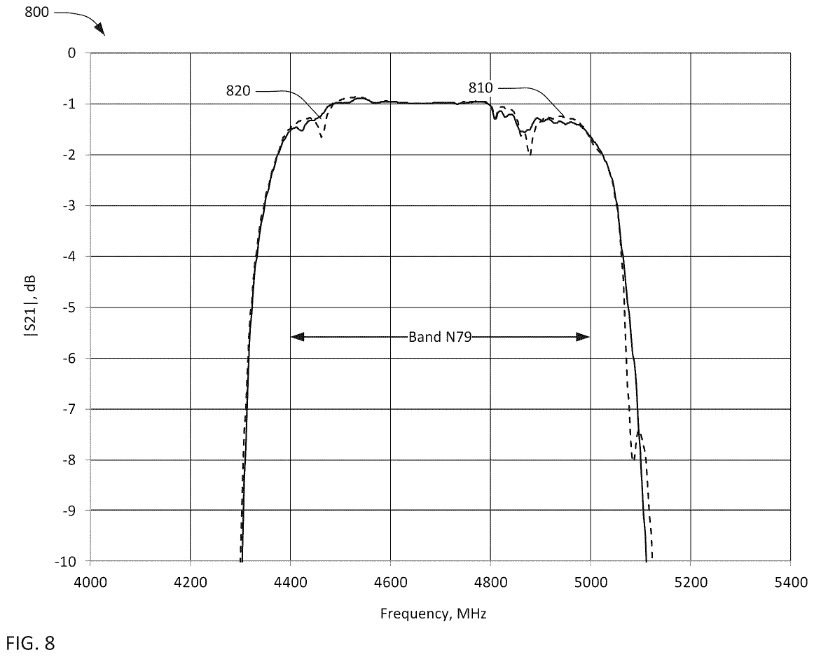

Slight variations in the mark of the IDT in an XBAR can result in disruption or destructive interference of spurious modes with negligible effect on the shear primary mode. This effect is illustrated in FIG. 8, which is an expanded view of a portion of the graph of FIG. 7. In FIG. 8, the dashed curve 810 is a plot of the S21 versus frequency for the filter with the conventional IDTs. The solid curve 820 is a plot of the of the S21 versus frequency of the filter with the multi-mark IDTs. The filter with multi-mark IDTs has reduced spurious modes within the Band N79 passband as compared to the filter with conventional IDTs, which can result in less loss. The chirped mark of the multi-mark IDT has a negligible effect on the resonance and anti-resonance frequencies of the shear primary acoustic mode of the XBAR.

The filters used to generate the data shown in FIGS. 7 and 8 include 4 series resonators and 4 shunt resonators in a ladder filter circuit. All resonators are XBARs. These filters are exemplary. A filter may have less or more resonators, and more or less series resonators and shunt resonators. Multi-mark IDTs may be divided into two sections or more than three sections, or may be continuous. The number of sections may not be the same for all resonators in a filter, and a filter may include both sectioned and continuous multi-mark IDTs. The value of δₘ may be different for some or all of the resonators. A filter may contain a combination of resonators with uniform mark and multi-mark resonators.

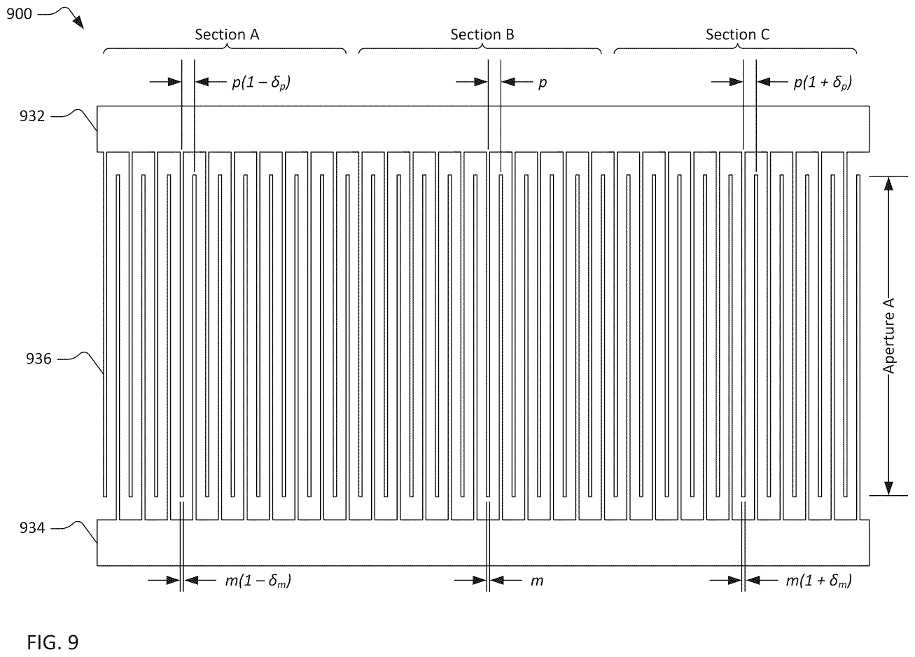

FIG. 9 is a plan view of an exemplary multi-pitch multi-mark IDT 900. A “multi-pitch IDT” is an IDT where the pitch of the IDT fingers varies along the length of the IDT. At any given point along the length, the pitch may not vary across the aperture of the IDT. Further, the mark can also vary along the length of the IDT, as described above, such that the IDT is a multi-mark multi-pitch IDT. The multi-pitch multi-mark IDT 900 may be a portion of an XBAR such as the XBAR 100 of FIG. 1.

The multi-pitch multi-mark IDT 900 includes a first busbar 932, and a second busbar 934, and a plurality of interleaved fingers such as finger 936. The interleaved fingers extend alternately from the first and second busbars 932, 934. As similarly described for FIG. 4 above, the multi-pitch multi-mark IDT 900 can be divided into three sections, identified as Section A, Section B, and Section C, along the length L of the IDT. Each of Sections A, B, and C includes 20 fingers, for a total of 60 fingers in the multi-pitch multi-mark IDT 900. The use of three sections and 60 fingers is exemplary. An IDT may have more than or fewer than 60 total fingers. An IDT may be divided along its length into two or more sections, each of which includes a plurality of adjacent fingers. The total number of fingers may be divided essentially equally between the two or more sections. In this context, “essentially” means “as close as possible.” For example, an IDT with 100 fingers divided into three sections with 33, 34, and 33 fingers is considered to be divided essentially equally. The total number of fingers may be divided unequally between the two or more sections. The divisions can be the same or different from the divisions for the chirping of the mark.

In this example, the fingers in Section B have pitch p, which is the nominal pitch of the IDT. The finger of Section A have a pitch of p(1−δₚ), and the fingers of Section C have a pitch of p(1+δₚ). δₚ is greater than 0 and less than or equal to 0.05. δₚ may typically be less than 0.01. δₚ may be selected during a filter design to achieve the most effective reduction of spurious modes. At any point along the length L of the IDT 900, the pitch is constant across the aperture A. The mark of the IDT fingers also varies by sections, similar to the variation by section of IDT 400 shown in FIG. 4. The mark can vary by the same section as the pitch or by different sections of the pitch. Alternatively, the mark can vary continuously, similar to the continuous variation of mark shown in FIG. 5.

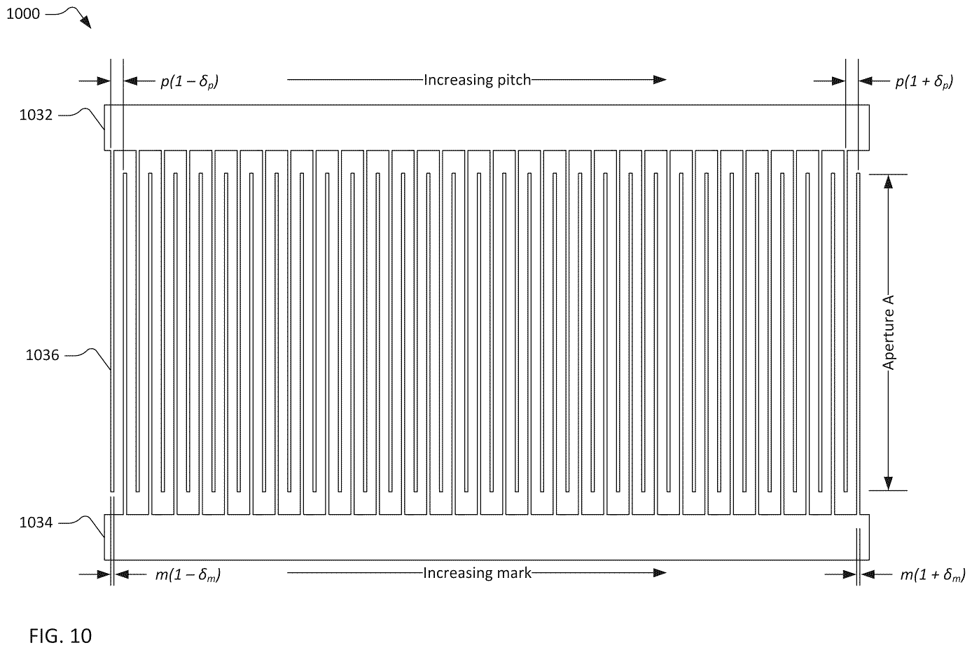

FIG. 10 is a plan view of another exemplary multi-pitch multi-mark IDT 1000. The multi-pitch multi-mark IDT 900 may be a portion of an XBAR such as the XBAR 100 of FIG. 1. The multi-pitch multi-mark IDT 1000 includes a first busbar 1032, and a second busbar 1034, and a plurality of interleaved fingers such as finger 1036. The interleaved fingers extend alternately from the first and second busbars 1032, 1034. In this example, the mark varies continuously, similar to the continuous variation of mark shown in FIG. 5. The pitch also varies continuously, similar to the mark. As shown in FIG. 10, the mark and pitch both increase continuously from left to right, as oriented in the figure. Alternatively, the either the mark or pitch could increase continuously from left to right, while the other of mark or pitch decreases continuously from left to right.

In other examples, the pitch of the IDT can vary continuously, similar to the continuous variation of mark shown in FIG. 5. The pitch may vary as the mark varies, or may vary at a different rate. The pitch and mark may both vary continuously. The pitch and/or the mark may vary between multiple maxima and minima along the length of the IDT. The mark may vary by section while the pitch varies continuously, or pitch may vary by section while the mark varies continuously. The mark may increase in one direction along the length of the IDT (either continuously or by section), while the pitch decreases in the same direction (either continuously or by section). Variation of mark and pitch can be optimized with respect to one another, and variation of mark and pitch can be different from one resonator to another, such that greatest suppression of spurious modes is achieved for best performance of the filter.

### Closing Comments

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

1. An acoustic resonator comprising:
a piezoelectric layer having at least a portion attached to a substrate either directly or via one or more intermediate layers; and
a conductor pattern on the piezoelectric layer, the conductor pattern comprising a multi-mark interdigital transducer (IDT) having a plurality of interleaved fingers extending from opposing busbars, and a length between outermost fingers of the interleaved fingers,
wherein the IDT is divided along the length into at least three sections, with each of a first section, a second section, and third section having multiple pairs of fingers of the plurality of interleaved fingers,
wherein a mark and a pitch of the interleaved fingers in each of the first, second and third sections are constant in each section,
wherein the mark in each section is different from the respective marks of the other sections, and
wherein a change in the mark between the at least three sections has a smaller effect on a resonance frequency of a primary shear acoustic mode of all of the at least three sections of the acoustic resonator in comparison to an effect that the change in the mark has on a spurious acoustic mode other than the primary shear acoustic mode of all of the at least three sections.

2. The acoustic resonator of claim 1, further comprising a cavity between the piezoelectric layer and the substrate.

3. The acoustic resonator of claim 2, wherein the cavity is an irregular polygon in shape.

4. The acoustic resonator of claim 1, wherein the primary shear acoustic mode is excited in response to a radio frequency signal applied to the IDT.

5. The acoustic resonator of claim 1, further comprising an acoustic reflector of multiple layers between the substrate and the piezoelectric layer.

6. The acoustic resonator of claim 1, wherein the mark is a width of an interleaved finger of the plurality of interleaved fingers, and the mark is measured in a direction substantially perpendicular to a direction of extension of the IDT finger of the plurality of interleaved fingers from a respective busbar among the opposing busbars.

7. The acoustic resonator of claim 1, wherein the acoustic resonator is one of a plurality of acoustic resonators of a filter, and the spurious acoustic mode is an in-band acoustic mode in a passband of the filter.

8. The acoustic resonator of claim 1, wherein the smaller effect is a smaller change in a primary shear acoustic mode amplitude than a change in a spurious acoustic mode amplitude.

9. The acoustic resonator of claim 1, wherein the piezoelectric layer and the IDT are configured such that a radio frequency signal applied to the IDT excites the primary shear acoustic mode in the piezoelectric layer, the primary shear acoustic mode being a bulk shear mode where acoustic energy propagates along a direction substantially orthogonal to the surface of the piezoelectric layer and that is orthogonal to a direction of an electric field generated by the IDT.

10. The acoustic resonator of claim 1, wherein the IDT is a multi-pitch IDT and the pitch in each section is different from the respective pitches of the other sections, and wherein the pitch in each section is measured as a center-to-center-spacing between adjacent fingers extending from different busbars in the respective section.

11. A filter device comprising:
a piezoelectric layer having at least a portion attached to a substrate either directly or via one or more intermediate layers; and
a conductor pattern on the piezoelectric layer, the conductor pattern comprising a plurality of interdigital transducers (IDTs) of a plurality of bulk acoustic resonators each having interleaved fingers extending from opposing busbars,
wherein each of a first IDT and a second IDT from the plurality of IDTs is a multi-mark IDT, and each of the first IDT and the second IDT have a respective length between outermost fingers of the interleaved fingers of the respective IDT,
wherein:
the first IDT and second IDT are each divided along the length into at least three sections, with each of a first section, a second section, and third section having multiple pairs of fingers of the plurality of interleaved fingers,
wherein a mark and a pitch of the interleaved fingers in each of the first, second and third sections are constant in each section of the respective IDT,
wherein the mark in each section of the first and second IDTs is different from the respective marks of the other sections, and
wherein a change in the mark between the at least three sections has a smaller effect on a resonance frequency of a primary shear acoustic mode of all of the at least three sections of all of the respective bulk acoustic resonators in comparison to an effect that the change in the mark has on a spurious acoustic mode of the filter device other than the primary shear acoustic mode of all of the at least three sections.

12. The filter device of claim 11, further comprising a cavity between the piezoelectric layer and the substrate.

13. The filter device of claim 11, wherein the change in mark between the at least three sections of the first IDT is different than the change in mark between the at least three sections of the second IDT.

14. The filter device of claim 11, further comprising an acoustic reflector of multiple layers between the substrate and the piezoelectric layer.

15. The filter device of claim 11, wherein the mark is a width of an interleaved finger of the interleaved fingers, and the mark is measured in a direction substantially perpendicular to a direction of extension of the interleaved finger from a respective busbar among the opposing busbars.

16. The filter device of claim 11, wherein the spurious acoustic mode is an in-band acoustic mode in a passband of the filter.

17. The filter device of claim 11, wherein the smaller effect is a smaller change in a primary shear acoustic mode amplitude than a change in a spurious acoustic mode amplitude.

18. The filter device of claim 11, wherein the piezoelectric layer and the IDT are configured such that a radio frequency signal applied to the IDT excites the primary shear acoustic mode in the piezoelectric layer, the primary shear acoustic mode being a bulk shear mode where acoustic energy propagates along a direction substantially orthogonal to a surface of the piezoelectric layer and that is orthogonal to a direction of an electric field generated by the IDT.

19. The filter device of claim 11, wherein the first IDT is a multi-pitch IDT, and the pitch in each section is different from the respective pitches of the other sections, and wherein the pitch in each section is measured as a center-to-center-spacing between adjacent fingers extending from different busbars in the respective section.

20. The filter device of claim 19, wherein the second IDT is a multi-pitch IDT, and the pitch in each section is different from the respective pitches of the other sections, and wherein the pitch is measured as a center-to-center-spacing between adjacent fingers extending from different busbars in the respective section, and the change in mark between the at least three sections of the first IDT is different than a change in mark between the at least three sections of the second IDT.
